(19) United States
(12) Patent Application Publication
(10) Pub. No.: US 2015/0147858 A1
(43) Pub. Date: May 28, 2015

(54) METHODS OF MANUFACTURING NON-VOLATILE MEMORY DEVICES

(71) Applicant: SAMSUNG ELECTRONICS CO., LTD., Suwon-si (KR)

(72) Inventors: Kyoung-Hoon KIM, Yongin-si (KR); Hong-Soo KIM, Seongnam-si (KR); Hoo-Sung CHO, Yongin-si (KR)

(21) Appl. No.: 14/567,345

(22) Filed: Dec. 11, 2014

Related U.S. Application Data
(62) Division of application No. 13/614,028, filed on Sep. 13, 2012, now abandoned.

(30) Foreign Application Priority Data
Nov. 1, 2011 (KR) 10-2011-0112648

(51) Int. Cl. H01L 29/66; H01L 27/115

(52) U.S. Cl. CPC H01L 29/66825; H01L 27/1157; H01L 27/11524; H01L 29/66833
USPC 438/279

(57) ABSTRACT

A non-volatile memory device includes a substrate including an active region and a field region, selection transistors and cell transistors on the active region, bit line contacts on the bridge portions, and shared bit lines electrically connected to the bit line contacts. The active region includes string portions and bridge portions. The string portions extend in a first direction and are arranged in a second direction substantially perpendicular to the first direction, and the bridge portions connect at least two adjacent string portions. Each bridge portion has a length in the first direction equal to or longer than about twice a width of each bit line contact in the first direction.

### CROSS-REFERENCE TO RELATED APPLICATIONS

This is a divisional application based on pending application Ser. No. 13/614,028, filed Sep. 13, 2012, the entire contents of which is hereby incorporated by reference.

Korean Patent Application No. 10-2011-0112648 filed on Nov. 1, 2011, in the Korean Intellectual Property Office, and entitled, “Non-Volatile Memory Devices and Methods of Manufacturing the Same,” is incorporated by reference herein in its entirety.

### BACKGROUND

1. Field

Example embodiments relate to non-volatile memory devices and methods of manufacturing the same. More particularly, example embodiments relate to highly integrated non-volatile memory devices and methods of manufacturing the same.

2. Description of the Related Art

NAND flash memory devices have been used as a main memory device of various types of electronic equipments because the NAND flash memory devices may store a large amount of data. Methods of manufacturing NAND flash memory devices having a high integration degree have been developed.

### SUMMARY

Embodiments are directed to a non-volatile memory device including a substrate including an active region and a field region, the active region including string portions and bridge portions, the string portions extending in a first direction and being arranged in a second direction substantially perpendicular to the first direction, and the bridge portions connecting at least two adjacent string portions, selection transistors and cell transistors on the active region, bit line contacts on the bridge portions, and shared bit lines electrically connected to the bit line contacts, wherein each bridge portion has a length in the first direction equal to or longer than about twice a width of each bit line contact in the first direction.

One of the bridge portions and a plurality of the string portions connected by the bridge portion may define a unit string, and the unit string may be repeated in the second direction.

The bit line contacts that are adjacent to each other in the second direction may be spaced apart at a maximum distance.

The bit line contacts may be arranged in a zigzag form or in one or more diagonal lines, each diagonal line including bit line contacts in three bridge portions.

The bridge portions may have an island shape and may be spaced apart from each other.

Each bridge portion may have two rectangular island shaped areas.

Each rectangular island shaped area may have a length in the first direction that is longer than a width of each bit line contact in the first direction.

Embodiments are also directed to a method of manufacturing a non-volatile memory device, the method including forming an etch stop layer pattern on a substrate, forming an etching mask on the substrate having the etch stop layer pattern thereon, etching the substrate using the etching mask and the etch stop layer pattern as an etch mask, the etching mask and the etch stop layer pattern being configured such that the etching of the substrate forms an active region and a field region, the active region including a plurality of string portions and a plurality of bridge portions, the string portions extending in a first direction and being arranged in a second direction substantially perpendicular to the first direction, and the bridge portions connecting at least two adjacent string portions, forming selection transistors and cell transistors on the active region, forming bit line contacts on the bridge portions, and forming shared bit lines electrically connected to the bit line contacts, wherein each bridge portion is formed to have a length in the first direction equal to or longer than about twice a width of each bit line contact in the first direction.

The forming of the etching mask may include forming a first temporary mask layer on the substrate, forming a plurality of first spacers on the first temporary mask layer, the first spacers extending in the first direction, etching the first temporary mask layer using the first spacers to form a plurality of first temporary masks, forming a plurality of second spacers on sidewalls of the first temporary masks, and removing the first temporary masks such that the second spacers remain to constitute the etching mask.

The forming of the first spacers may include forming a plurality of second temporary masks on the first temporary mask layer, forming the first spacers on sidewalls of the second temporary masks, and removing the second temporary masks.

The forming of the etch stop layer pattern may include forming a preliminary etch stop layer pattern on the substrate, the preliminary etch stop layer pattern extending in the second direction, and etching the preliminary etch stop layer pattern using the first temporary masks and the second spacers as an etching mask.

The bridge portions may each be formed to have a rectangular island shape, and the preliminary etch stop layer pattern has a length in the first direction equal to or longer than about twice a width of each bit line contact in the first direction.

Each bridge portion may be formed to include at least two rectangular island shaped areas in the first direction. The preliminary etch stop layer pattern may have a length in the first direction that is equal to or longer than a width of each bit line contact in the first direction.

The bit line contacts may be arranged in a zigzag form or in one or more diagonal lines, each diagonal line including bit line contacts in three bridge portions.

The bit line contacts that are adjacent to each other in the second direction may be spaced apart at a maximum distance.

Embodiments are also directed to a non-volatile memory device, including a substrate including an active region, the active region including string portions and bridge portions forming a plurality of unit cell strings, each unit cell string including at least two of the string portions extending in a first direction and one of the bridge portions connecting the at least two string portions, the unit cell strings being arranged such that the bridge portions form a row in a second direction different from the first direction, selection transistors and cell transistors on the active region, and bit line contacts on the bridge portions, one bit line contact being on each bridge portion, wherein each bit line contact is arranged on a respective bridge portion such that bit line contacts on adjacent bridge portions do not overlap in the second direction.

Each bridge portion may have a length in the first direction that is equal to or longer than about twice a width of each bit line contact in the first direction, and the bit line contacts are arranged in a zigzag pattern in the second direction.

Each bridge portion may have two island shaped areas between the at least two string portions, the at least two string portions being spaced apart from each other in the first direction, each of the rectangular shaped areas having a length in the first direction that is greater than the width of the bit line contact in the first direction.

Each bridge portion may have a length in the first direction that is equal to or longer than about three times a width of each bit line contact in the first direction. The bit line contacts may be arranged in a repeating pattern in the second direction in which three adjacent bit line contacts form a diagonal line across three adjacent bridge portions.

Each bridge portion may have three island shaped areas between the at least two string portions, the three island shaped areas being spaced apart from each other in the first direction, each of the island shaped areas having a length in the first direction that is greater than the width of the bit line contact in the first direction.

### BRIEF DESCRIPTION OF THE DRAWINGS

Features will become apparent to those of skill in the art by describing in detail exemplary embodiments with reference to the attached drawings in which:

FIG. 1 illustrates a block diagram depicting a non-volatile memory device in accordance with example embodiments;

FIG. 2 illustrates a circuit diagram depicting a memory cell array of a non-volatile memory device in accordance with example embodiments;

FIG. 3A illustrates a plan view depicting a memory cell array of a non-volatile memory device in accordance with example embodiments;

FIG. 3B illustrates a cross-sectional view cut along the line I-I′ in FIG. 3A;

FIGS. 4A to 4H illustrate plan views depicting stages of a method of manufacturing the non-volatile memory device in FIGS. 3A and 3B;

FIGS. 5A to 5H illustrate cross-sectional views depicting stages of the method of manufacturing the non-volatile memory device in FIGS. 3A and 3B, the cross-sectional views of FIGS. 5A to 5H being cut along the line I-I′ of FIG. 3A;

FIGS. 6A to 6H illustrate cross-sectional views depicting stages of the method of manufacturing the non-volatile memory device in FIGS. 3A and 3B, the cross-section views of FIGS. 6A to 6H being cut along the line II-IF of FIG. 3A;

FIGS. 7A and 7B illustrate cross-sectional views depicting stages of a method of manufacturing the non-volatile memory device of FIG. 3A in accordance with example embodiments;

FIG. 8 illustrates a plan view depicting a memory cell array of a non-volatile memory device in accordance with example embodiments;

FIG. 9A illustrates a plan view depicting a memory cell array of a non-volatile memory device in accordance with example embodiments;

FIG. 9B illustrates a cross-sectional view cut along the line I-I′ in FIG. 9A;

FIGS. 10A to 10D illustrate plan views depicting stages of a method of manufacturing the non-volatile memory device in FIGS. 9A and 9B;

FIGS. 11A to 11D illustrate cross-sectional views depicting stages of the method of manufacturing the non-volatile memory device in FIGS. 9A and 9B, the cross-sectional view of 11A to 11D being cut along the line I-I′ of FIG. 9A;

FIG. 12 illustrates a plan view depicting a memory cell array of a non-volatile memory device in accordance with example embodiments; and

FIG. 13 illustrates a diagram depicting an electronic system in accordance with example embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope thereof to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

It will be understood that, although the terms first, second, third, etc., may be used herein to describe various elements, components, regions, layers, and/or sections, these elements, components, regions, layers and/or sections should not be limited by these terms. These terms are only used to distinguish one element, component, region, layer, or section from another element, component, region, layer or section. Thus, a first element, component, region, layer, or section discussed below could be termed a second element, component, region, layer, or section without departing from the teachings thereof.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

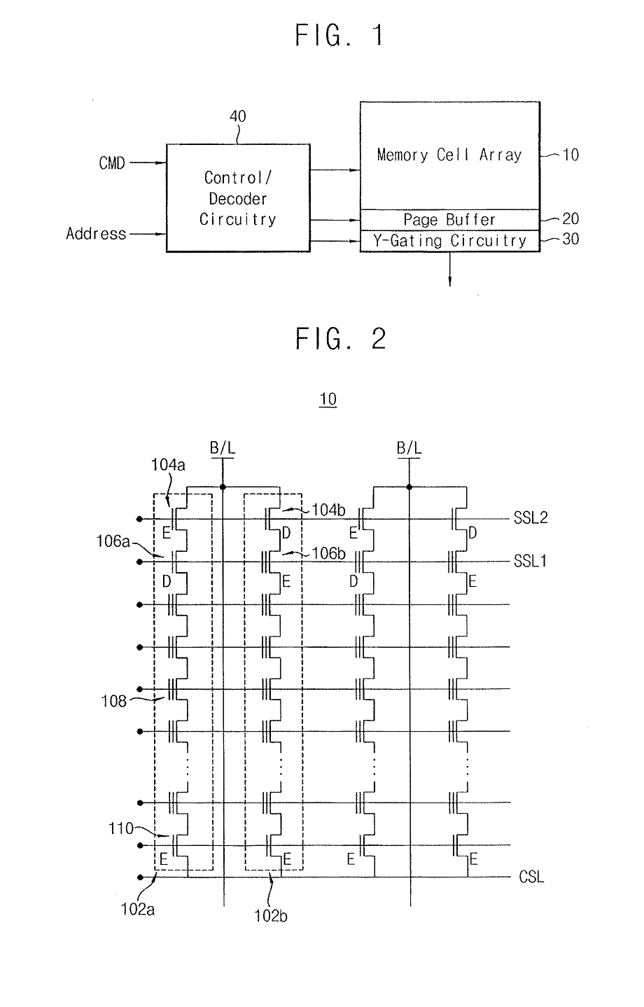

FIG. 1 is a block diagram illustrating a non-volatile memory device in accordance with example embodiments, and FIG. 2 is a circuit diagram illustrating a memory cell array of a non-volatile memory device in accordance with example embodiments.

Referring to FIG. 1, the non-volatile memory device may include a memory cell array 10, a page buffer 20, a Y-gating circuitry 30, and a control/decoder circuitry 40. The memory cell array 10 may include a plurality of memory blocks, and each memory block may include a plurality of memory cells. The page buffer 20 may temporarily store data to be written in the memory cell array 10 or read data from the memory cell array 10. The Y-gating circuitry 30 may transfer data stored in the page buffer 20. The control/decoder circuitry 40 may receive command (CMD) and address signals, output a control signal for writing data in the memory cell array 10 or reading data from the memory cell array, and decode the address. The control/decoder circuitry 40 may output a signal for inputting/outputting data into/from the page buffer 20, and provide address information to the Y-gating circuitry 30.

Referring to FIG. 2, the memory cell array 10 may include a first cell string 102a, a second cell string 102b, a shared bit line B/L commonly connected to end portions of the first and second strings 102a and 102b, and a common source line (CSL) connected to end portions of the first and second strings 102a and 102b.

The memory cell array 10 may include a plurality of unit cell strings each of which may have one shared bit line B/L and 2 strings 102a and 102b connected to the shared bit line B/L. In other implementations, each unit cell string may have one shared bit line B/L and more than 2 strings 102a and 102b.

Particularly, the first cell string 102a may include a first selection transistor 104a, a second selection transistor 106a, cell transistors 108 and a ground selection transistor 110 that may be sequentially connected in series.

The second cell string 102b may include a third selection transistor 104b, a fourth selection transistor 106b, cell transistors 108 and a ground selection transistor 110 that may be sequentially connected in series.

Gates of the transistors in each string may be connected, i.e., the gates in the strings may be connected to form gate lines, e.g., string selection lines SSL1 and SSL2, word lines W/L and a ground selection line (GSL). Each gate line may extend in a direction substantially perpendicular to an extension direction of the strings.

In order to select one of two strings 102a and 102b connected to the shared bit line B/L, two selection transistors having different threshold voltages may be connected in series, and each transistor sharing a gate line in the two strings 102a and 102b may have different threshold voltages. For example, first and fourth selection transistors 104a and 106b may be enhancement mode transistors E, and second and third selection transistors 106a and 104b may be depletion mode transistors D. Thus, one of the first and second cell strings 102a and 102b may be in a turn-on state.

The non-volatile memory device may have improved integration degree by connecting two or more strings to one shared bit line B/L.

The memory cell array shown in FIG. 2 may be implemented as various types.

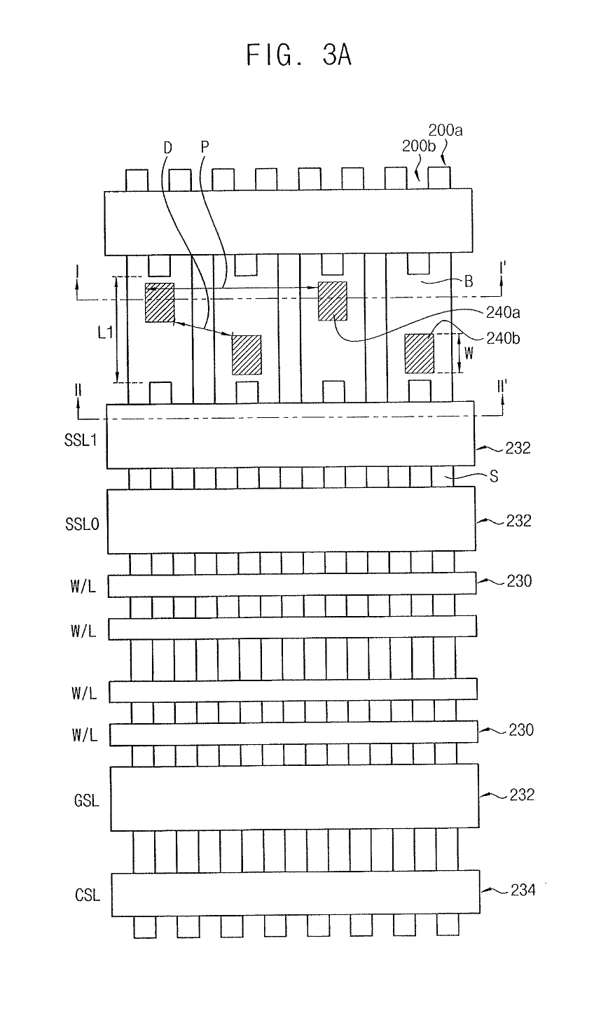

FIG. 3A is a plan view illustrating a memory cell array of a non-volatile memory device in accordance with example embodiments, and FIG. 3B is a cross-sectional view cut along the line I-I′ in FIG. 3A.

Referring to FIGS. 3A and 3B, a substrate 200 may have a plurality of isolation layers 205 thereon. The isolation layers 205 may be formed in a plurality of trenches 220 on the substrate 200. The substrate 200 may be divided into an active region 200a and a field region 200b. The field region 200b may be a region under the isolation layers 205, and the active region 200a may be a region defined by sidewalls of the isolation layers 205 and may protrude from bottoms of the isolation trenches 220.

The active region 200a may include a plurality of string portions S extending in a first direction and bridge portions B, each of which may connect the string portions S adjacent to each other in a second direction substantially perpendicular to the first direction.

The string portions S may be arranged parallel to each other in the second direction. Cell strings may be formed on the string portions S.

Each bridge portion B may serve as a pad region on which a bit line contact 240a or 240b may be formed. Each bridge portion B may connect more than one string portion S having a linear or bar shape. In the present embodiment, each bridge portion B connects two linear string portions S.

Each bridge portion B and string portions S connected by the bridge portion B may form a unit string, and a plurality of unit strings may be arranged in the second direction.

Each bridge portion B may have a rectangular shape in which a length along the first direction may be longer than that along the second direction. The length L1 along the first direction may be equal to or longer than about twice a width W of each of the bit line contacts 240a and 240b. Herein, the term “width W” with respect to a bit line contact may refer to a width along the first direction.

Each bridge portion B may have the length L1 equal to or longer than about twice the width W of each of the bit line contacts 240a and 240b, and thus an area of the bit line contacts 240a and 240b may be equal to or smaller than half of an area of each bridge portion B. Accordingly, an area of each bridge portion B in which a bit line contact 240a or 240b is not formed may be larger than the area of the bit line contact 240a or 240b.

In the active region 200a, a string selection transistor, cell transistors and a ground selection transistor may be formed on the string portions S. Gates of the transistors may be connected, i.e., the gates may be connected to form gate lines, e.g., string selection line SSL, word lines W/L and a ground selection line (GSL) extending in the second direction.

The string selection transistor, the ground selection transistor and the cell transistors therebetween may be connected in series to form a cell string. A plurality of cell strings may form a memory block.

Each cell transistor may include a tunnel insulation layer pattern, a charge storage layer pattern, a blocking layer pattern and a control gate sequentially stacked on the substrate 200. The charge storage layer pattern may be a floating gate electrode or a charge trapping layer pattern.

The string selection transistor and the ground selection transistor may have substantially the same structure as that of the cell transistors. In other implementations, the charge storage layer pattern and the control gate of the string selection transistor and the ground selection transistor may be connected to each other.

A common source line CSL electrically connected to a source region of the GSL may be formed. The CSL may be parallel to the GSL.

An insulating interlayer 236 covering the selection transistors and the cell transistors may be formed on the substrate 200. The bit line contacts 240a and 240b may be arranged in respective bridge portions B so that a distance D between adjacent bit line contacts 240a and 240b may be maximized. In the present embodiment, the bit line contacts 240a and 240b may be arranged in zigzag form.

More particularly, the first bit line contacts 240a that are arranged at an odd line from the left may contact upper portions of the bridge portions B, and the second bit line contacts 240b that are arranged at an even line from the left may contact lower portions of the bridge portions B, the upper and lower portions of the bridge portions B being defined in the first direction. The first and second bit line contacts 240a and 240b may not overlap in the second direction.

The bit line contacts 240a and 240b may be arranged in zigzag form, and thus the bit line contacts 240a and 240b may be spaced apart from each other at a maximum distance D.

For example, when a distance between the string portions S and a width of the string portions S are about 15 nm, respectively, each bridge portion B may have a width of about 45 nm. The bit line contacts 240a and 240b may be arranged in zigzag form, and thus a pitch P of repeating ones of bit line contacts 240a in the second direction may be about 120 nm.

As described above, the pitch P of the bit line contacts 240a and 240b and the distance D therebetween may be increased so that the bit line contacts 240a and 240b may not contact each other undesirably.

Shared bit lines (not shown) each of which may extend in the first direction may be formed on the bit line contacts 240a and 240b, respectively.

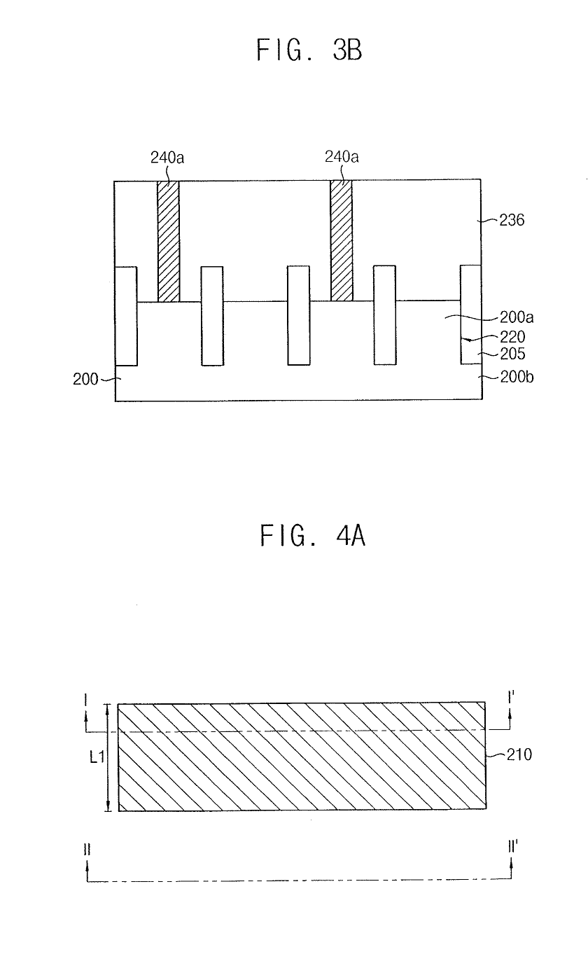

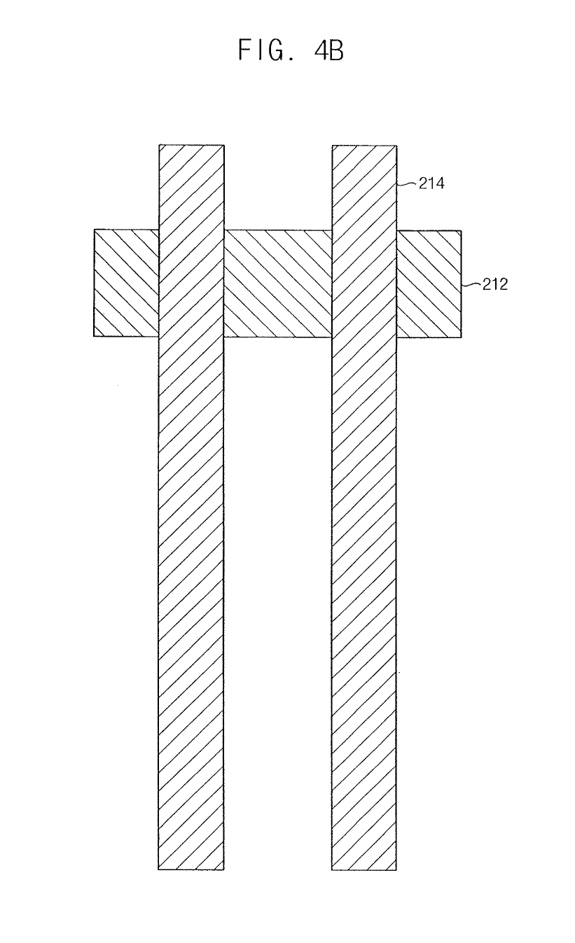

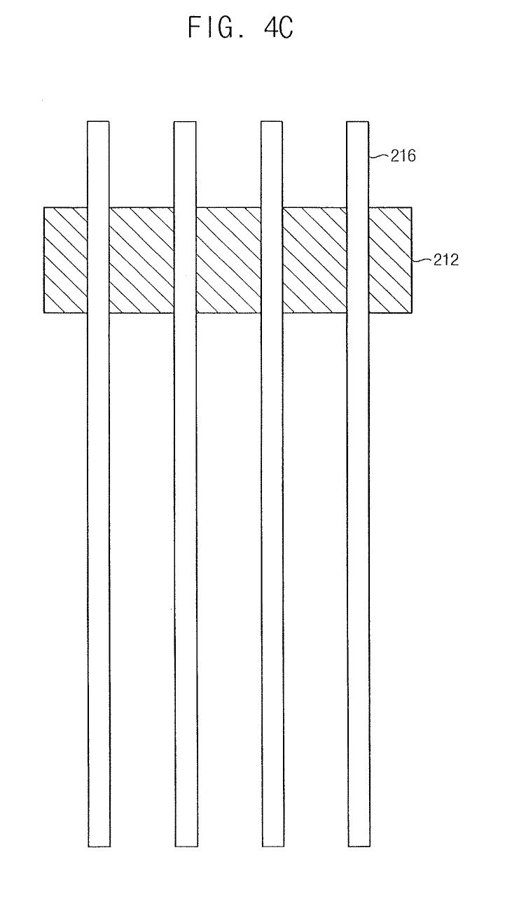

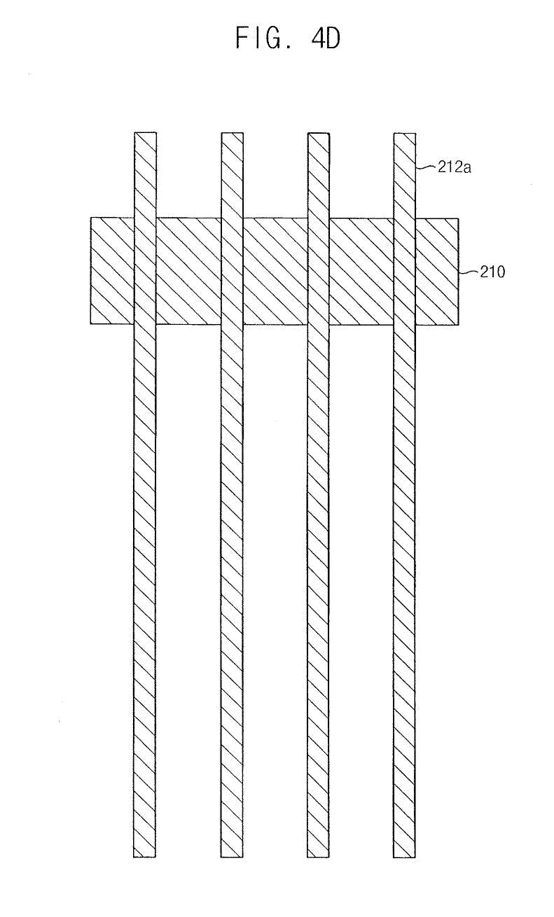

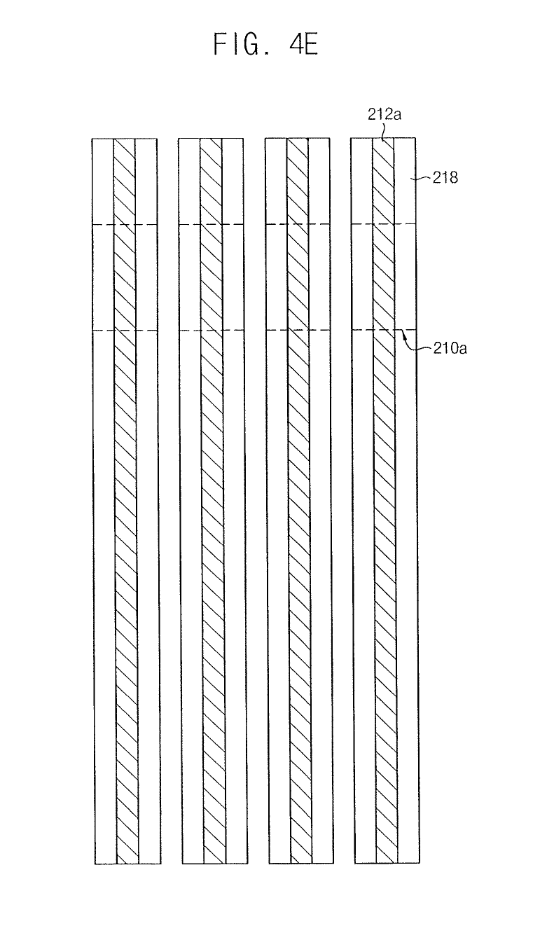

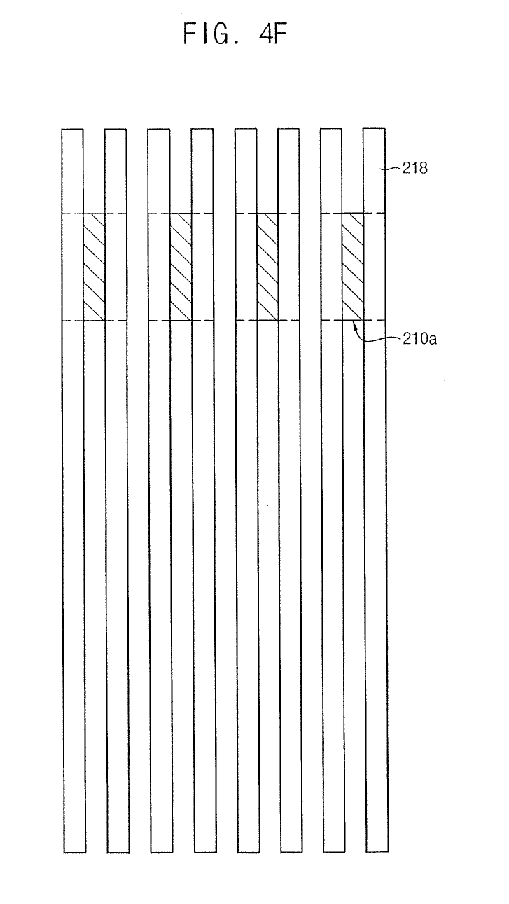

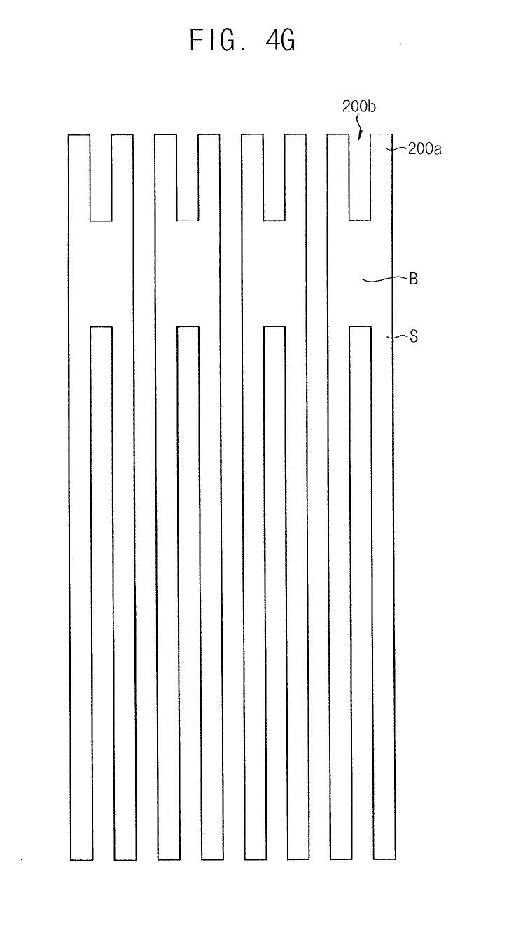

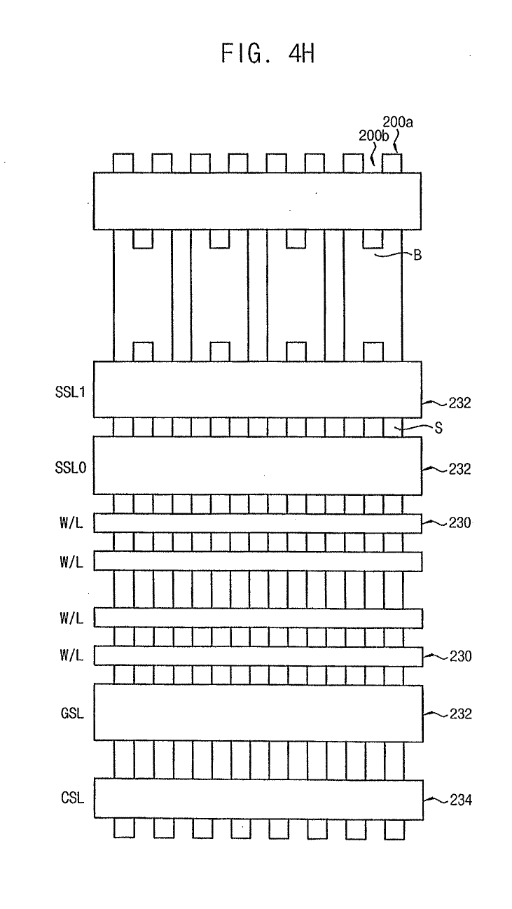

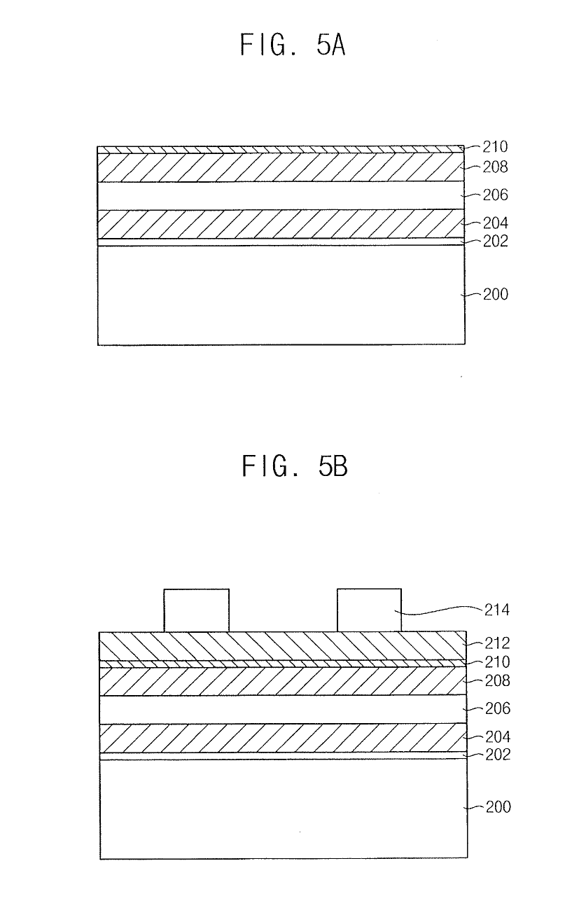

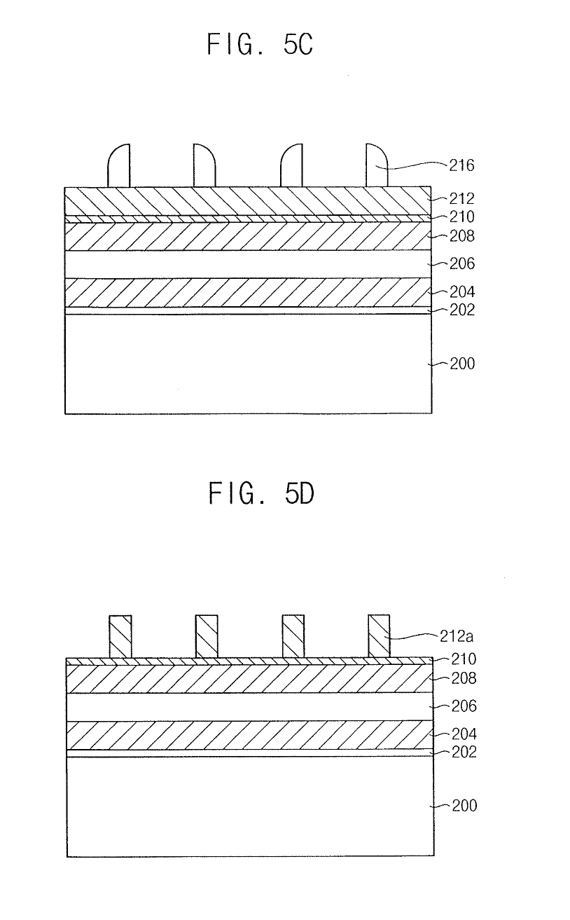

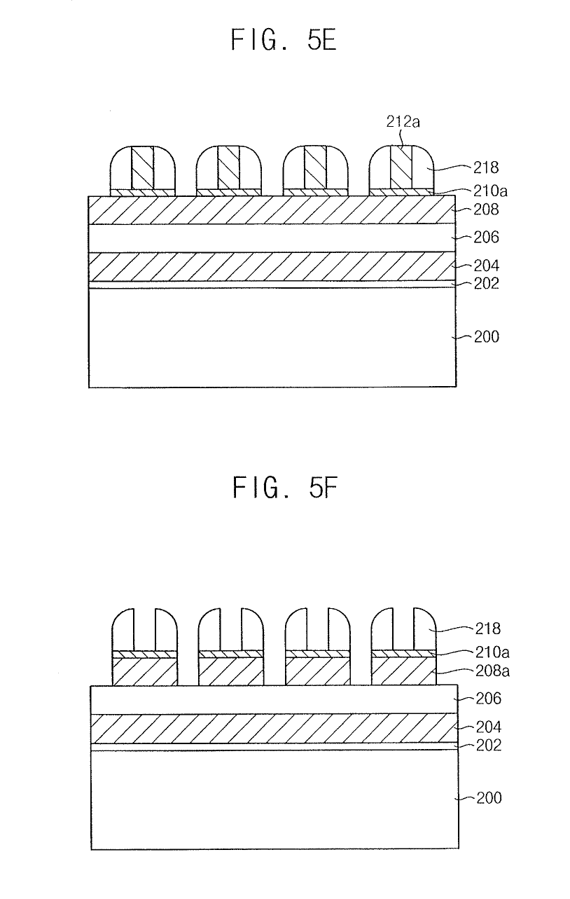

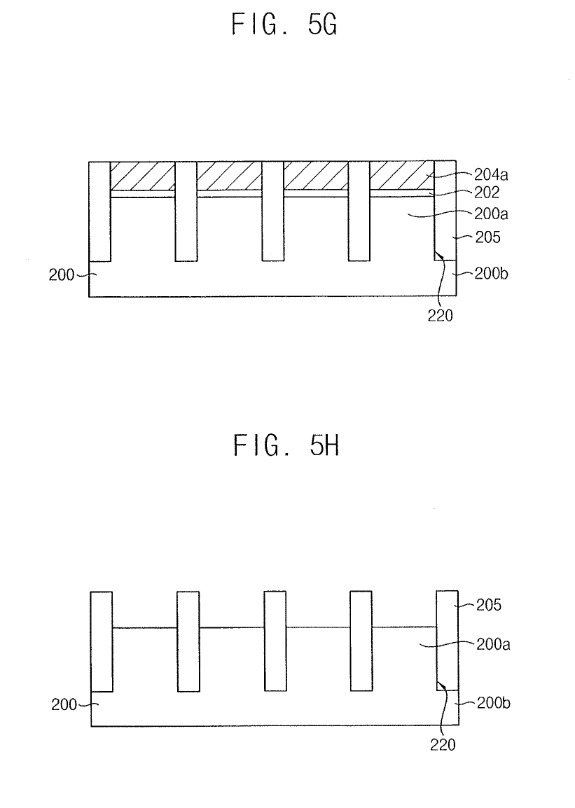

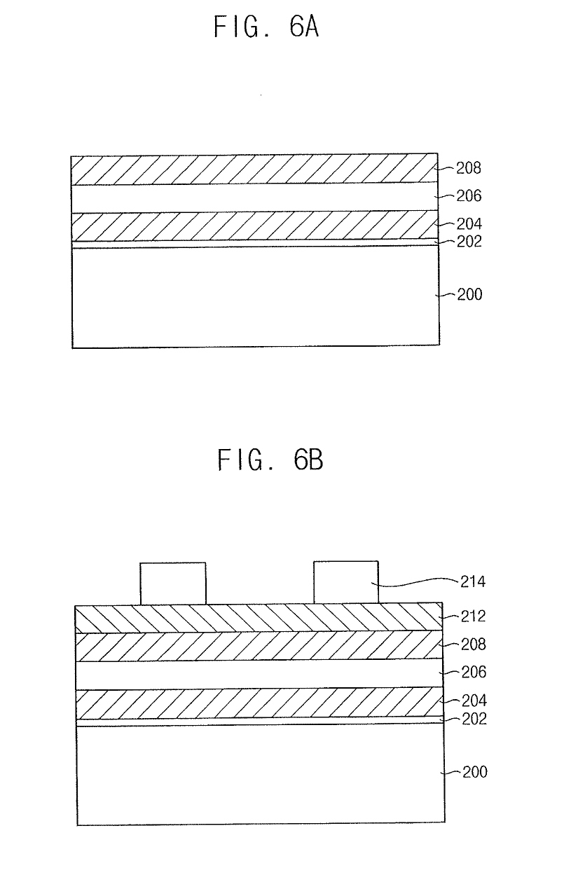

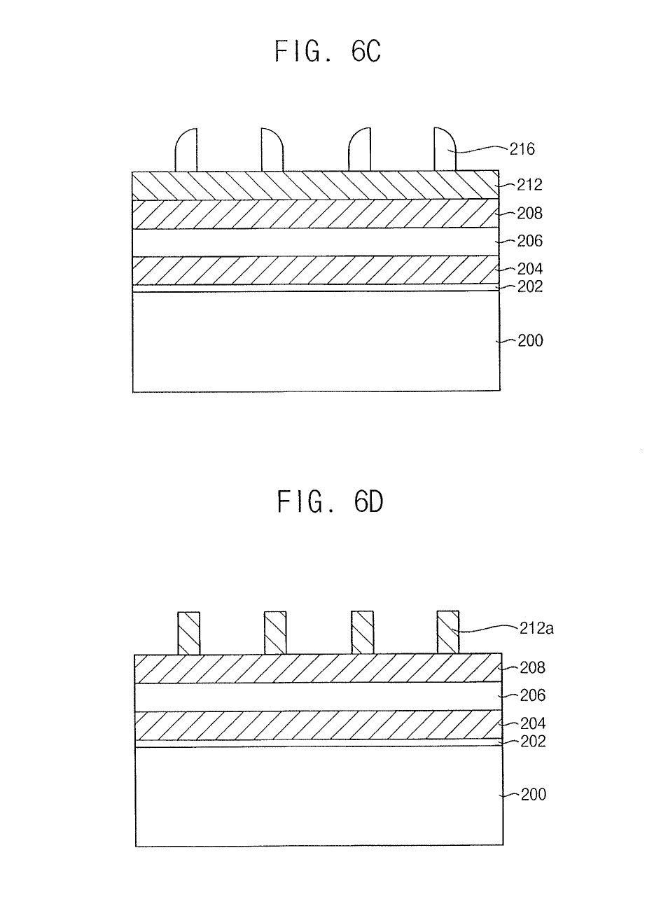

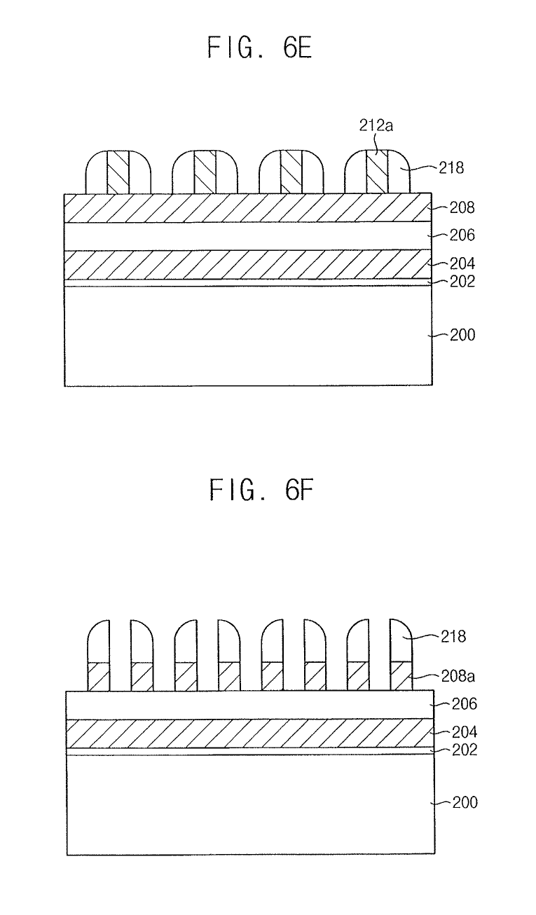

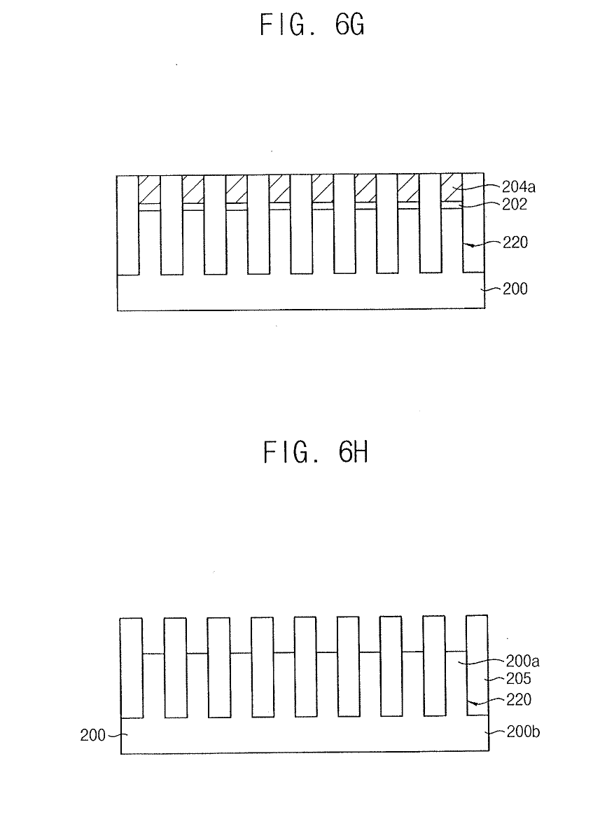

FIGS. 4A to 4H are plan views illustrating stages of a method of manufacturing the non-volatile memory device in FIGS. 3A and 3B. FIGS. 5A to 5H are cross-sectional views depicting the stages of the method of manufacturing the non-volatile memory device in FIGS. 3A and 3B, the cross-sectional views of 5A to 5H being cut along the line I-I′ of FIG. 3A. FIGS. 6A to 6H are cross-sectional views depicting the stages of the method of manufacturing the non-volatile memory device in FIGS. 3A and 3B, the cross-section views of FIGS. 6A to 6H being cut along the line II-II′ of FIG. 3A.

In the present embodiment, an active region may be formed by a quadruple patterning technology (QPT) including one photolithography process and two double patterning processes.

Referring to FIGS. 4A, 5A, and 6A, a pad layer 202, a first hard mask layer 204, an insulation layer 206, a second hard mask layer 208, and an etch stop layer may be sequentially formed on a substrate 200.

The first and second hard mask layers 204 and 208 may be formed using polysilicon. The insulation layer 206 may be formed using silicon oxide. The insulation layer 206 may be formed by a plasma enhanced chemical vapor deposition (PECVD) process. The etch stop layer may be formed using a material having an etching selectivity with respect to silicon oxide. For example, the etch stop layer may be formed using silicon nitride.

The etch stop layer may be partially etched to form a preliminary etch stop layer pattern 210 covering bridge portions B (refer to FIG. 3A) of the active region that may be subsequently formed and extending in a second direction. The preliminary etch stop layer pattern 210 may serve as an etching mask for patterning the bridge portions B. The preliminary etch stop layer pattern 210 may be formed to have a length L1 in a first direction substantially perpendicular to the second direction equal to or longer than about twice a width of each of bit line contacts 240a and 240b (refer to FIG. 3A) that may be formed subsequently.

Referring to FIGS. 4B, 5B, and 6B, a first temporary mask layer 212 may be formed on the preliminary etch stop layer pattern 210 and the second hard mask layer 208. The first temporary mask layer 212 may be formed to include, e.g., an amorphous carbon layer (ACL). An anti-reflective layer (ARL) (not shown) may be further formed on the first temporary mask layer 212 using silicon oxynitride.

A second preliminary mask layer may be formed on the ARL. The second temporary mask layer may be formed using a polymer that is easily removed by an ashing process and/or a stripping process. For example, the second temporary mask layer may be formed using a silicon-based spin-on hardmask (Si-SOH) or a carbon-based spin-on hardmask (C-SOH).

A photoresist pattern (not shown) may be formed from the second temporary mask layer by a photolithography process. The second temporary mask layer may be patterned using the photoresist pattern as an etching mask to form a plurality of second temporary masks 214.

Each second temporary mask 214 may extend in the first direction. Each second temporary mask 214 may be formed to have a width equal to about three times a width of each string portion S (refer to FIG. 3A) of the active region that may be subsequently formed. Additionally, the second temporary masks 214 may be formed to be spaced apart from each other at a distance about five times the width of each string portion S of the active region.

Referring to FIGS. 4C, 5C, and 6C, a first spacer layer may be formed on the second temporary masks 214 and the first temporary mask layer 212. The first spacer layer may be formed using silicon oxide. The first spacer layer may be formed by, e.g., an atomic layer deposition (ALD) process. The first spacer layer may be formed to have a thickness substantially the same as the width of each string portion S.

The first spacer layer may be anisotropically etched to form a plurality of first spacers 216. The first spacers 216 may be formed on sidewalls of the second temporary masks 214 and may extend in the first direction.

The second temporary masks 214 may be removed so that only the first spacers 216 remain on the first temporary mask layer 212. The second temporary masks 214 may be removed by an ashing process and/or a stripping process.

As shown in FIGS. 4C and 5C, each first spacer 216 may extend in the first direction and may have a width substantially the same as that of each string portion S. Additionally, the first spacers 216 may be spaced apart from each other at a distance about three times the width of each string portion S.

Referring to FIGS. 4D, 5D, and 6D, the first temporary mask layer 212 may be etched using the first spacers 216 as an etching mask to form a plurality of first temporary masks 212a on the preliminary etch stop layer pattern 210 and the second hard mask layer 208. The first temporary masks 212a may have a width substantially the same as the width of each string portion S. Additionally, the first temporary masks 212a may be spaced apart from each other at a distance about three times the width of each string portion S.

The first spacers 216 may be removed.

Referring to FIGS. 4E, 5E, and 6E, a second spacer layer may be formed on the first temporary masks 212a, the preliminary etch stop layer pattern 210 and the second hard mask layer 208. The second spacer layer may be formed using silicon oxide. The second spacer layer may be formed by e.g., an ALD process. The second spacer layer may be formed to have a thickness substantially the same as the width of each string portion S.

The second spacer layer may be anisotropically etched to form a plurality of second spacers 218. The second spacers 218 may be formed on sidewalls of the first temporary masks 212a. Each second spacer 218 may extend in the first direction. The preliminary etch stop layer pattern 210 may be etched using the second spacers 218 as an etching mask to form a plurality of etch stop layer patterns 210a. The etch stop layer patterns 210a may cover the bridge portions B and may each have an rectangular island shape, spaced apart from each other.

Referring to FIGS. 4F, 5F, and 6F, the first temporary masks 212a may be removed. Thus, portions of the etch stop layer patterns 210a between the spacers 218 may be exposed.

The second hard mask layer 208 may be etched using the etch stop layer patterns 210a and the second spacers 218 as an etching mask to form a plurality of second hard masks 208a on the insulation layer 206.

Referring to FIGS. 4G, 5G and 6G, the insulation layer 206 and the first hard mask layer 204 may be etched using the second hard masks 208a as an etching mask to form an insulation layer pattern (not shown) and a plurality of first hard masks 204a.

The first hard masks 204a may serve as an etching mask for forming isolation trenches 220. The first hard masks 204a may cover the active region including the string portions S and the bridge portions B.

The pad layer 202 and the substrate 200 may be etched using the first hard mask 204a as an etching mask to form the isolation trenches 220. The insulation layer pattern on the first hard masks 204a may be removed during the etching process.

An insulating material, e.g., silicon oxide may be filled into the isolation trenches 220 and planarized to form a plurality of isolation layers 205 in the isolation trenches 220. The substrate 200 may be divided into the active region 200a and a field region 200b by the isolation layers 205. Portions of the substrate 200 under the isolation layers 205 may be defined as the field region 200b, and portions of the substrate 200 between sidewalls of the isolation layers 205 may be defined as the active region 200a. The active region 200a may protrude from bottoms of the isolation trenches 220.

As illustrated above, the active region may include string portions S, each of which may extend in the first direction, and bridge portions B, each of which may connect at least adjacent two string portions S. Each bridge portion B may have a length in the first direction equal to or longer than about twice a width of each of the bit line contacts 240a and 240b, and, thus, the bit line contacts 240a and 240b may be easily formed.

Referring to FIGS. 4H, 5H and 6H, the first hard masks 204a and the pad layer 202 may be removed so that a top surface of the active region may be exposed. A tunnel insulation layer, a charge storage layer, a blocking layer, and a control gate layer may be sequentially formed on the exposed top surface of the active region and patterned to form a tunnel insulation layer pattern, a charge storage layer pattern, a blocking layer pattern, and a control gate. Thus, a first gate structure 230 for a cell transistor and a second gate structure 232 for a selection transistor may be formed. Impurities, e.g., n-type impurities, may be implanted into the active region adjacent to the first and second gate structures 230 and 232 to form impurity regions. Thus, cell transistors, string selection transistors, and ground selection transistors may be formed.

A common source line (CSL) 234 may be formed to be electrically connected to a source region of the ground selection transistor.

Referring to FIGS. 3A and 3B, an insulating interlayer 236 may be formed to cover the first and second gate structures 230 and 232 and the CSL 234.

The insulating interlayer 236 may be partially etched to form bit line contact holes exposing the bridge portions B of the active region. The bit line contact holes may be formed to be arranged in a zigzag form.

A conductive material may be filled into the bit line contact holes to form bit line contacts 240a and 240b.

The bit line contacts 240a and 240b may be arranged in zigzag form, so that adjacent bit line contacts 240a and 240b may be spaced apart from each other at a long distance. Thus, the bit line contacts 240a and 240b may not be undesirably electrically connected to each other.

Shared bit lines (not shown) may be formed on the insulating interlayer 236 to make contact with the bit line contacts 240a and 240b, respectively. Each shared bit line may be formed to extend in the first direction.

By the above-illustrated processes, the non-volatile memory device may be manufactured.

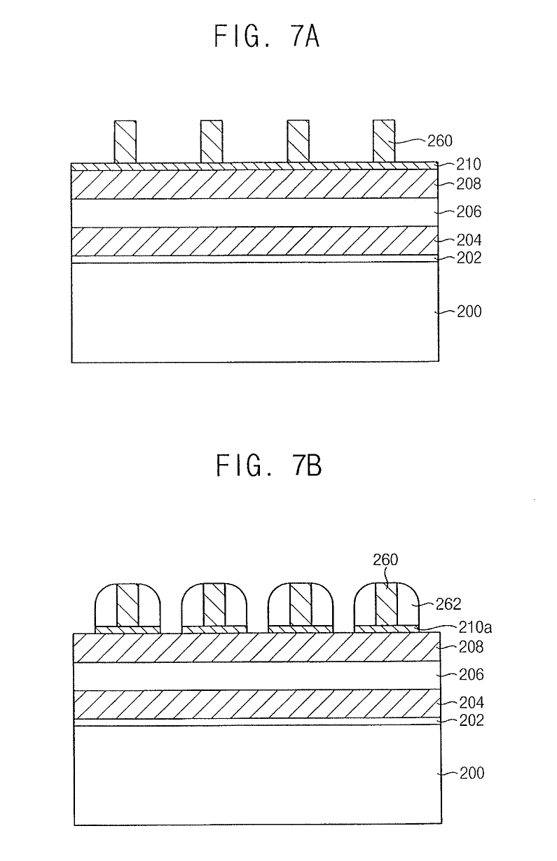

FIGS. 7A and 7B are cross-sectional views illustrating stages of a method of manufacturing the non-volatile memory device of FIG. 3A in accordance with example embodiments. The cross-section views of FIGS. 7a and 7B are cut along the line I-I′ of FIG. 3A.

In the present embodiment, an active region may be formed by one photolithography process and one double patterning process.

Referring to FIG. 7A, a pad layer 202, a first hard mask layer 204, an insulation layer 206, a second hard mask layer 208, and an etch stop layer may be sequentially formed on a substrate 200. The etch stop layer may be patterned to form a preliminary etch stop layer pattern 210. The preliminary etch stop layer pattern 210 may be formed by a process substantially the same as that illustrated with reference to FIG. 5A.

A temporary mask layer (not shown) may be formed on the preliminary etch stop layer pattern 210. The temporary mask layer may be formed using a polymer that is easily removed by an ashing process and/or a stripping process. For example, the temporary mask layer may be formed to include Si-SOH or C-SOH.

The temporary mask layer may be patterned to form a photoresist pattern (not shown). The photoresist pattern may be formed to have a plurality of lines each of which may extend in a first direction. Each line of the photoresist pattern may have a width substantially the same as a width of each string portion S. The lines of the photoresist pattern may be spaced apart from each other at a distance equal to about three times the width of each string portion S. The temporary mask layer may be etched using the photoresist pattern as an etching mask to form a plurality of temporary masks 260.

Referring to FIG. 7B, a first spacer layer may be formed on the temporary masks 260 and the preliminary etch stop layer pattern 210. The first spacer layer may be formed to have a thickness substantially the same as the width of each string portion S. The first spacer layer may have the thickness substantially the same as the width of each string portion S, and thus a recess defined by a top surface of the first spacer layer may have a width substantially the same as the width of each string portion S. The first spacer layer may be anisotropically etched to form a plurality of first spacers 262.

Portions of the preliminary etch stop layer pattern 210 that are not covered by the first spacers 262 or the temporary masks 260 may be removed so that an etch stop layer pattern 210a may be formed.

By performing processes substantially the same as those illustrated with reference to FIGS. 4E to 4H, 5F to 5H, 6F to 6H and 3A to 3B, the non-volatile memory device may be manufactured.

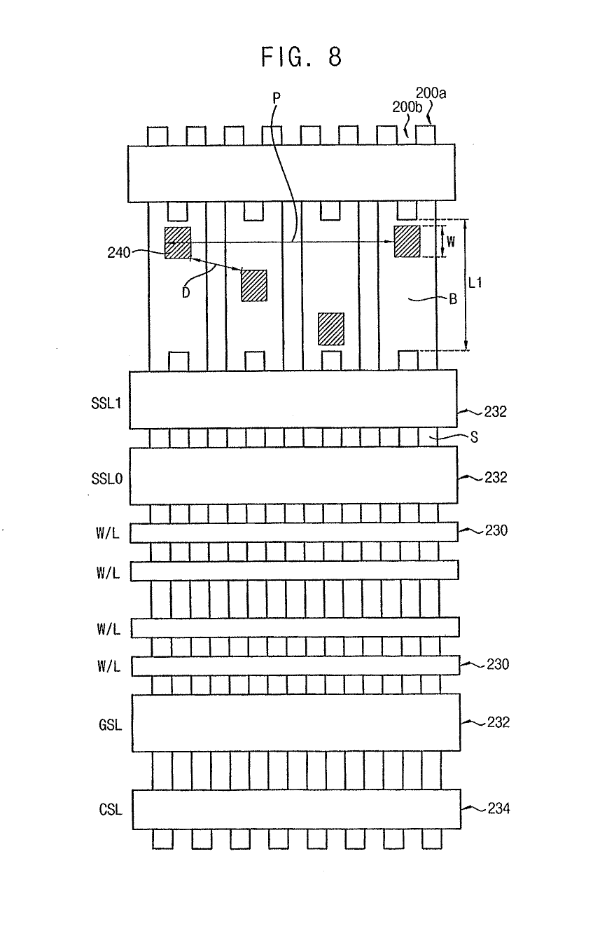

FIG. 8 is a plan view illustrating a memory cell array of a non-volatile memory device in accordance with example embodiments.

The non-volatile memory device of FIG. 8 may be substantially the same as that of FIGS. 3A and 3B, except for a length of each bridge portion in a first direction and a layout of bit line contacts.

Referring to FIG. 8, each bridge portion B may have a length L1 in the first direction that is equal to or longer than about three times the width W of each bit line contact 240. Bit line contacts 240 may be arranged not in zigzag form, but instead in a diagonal line in three bridge portions B. That is, when viewed in the first direction, one bit line contact 240 may be in an upper portion of the bridge portion B, another bit line contact 240 may be in a central portion of the bridge portion B, and the other bit line contact 240 may be in a lower portion of the bridge portion B. The above layout of the bit line contacts 240 may be repeated in every three bridge portions B.

Thus, the bit line contacts 240 may be arranged to be spaced apart from each other at an enlarged distance.

As illustrated above, the non-volatile memory device in FIG. 8 may be substantially the same as that of FIGS. 3A and 3B except for the length of each bridge portion B in the first direction and the layout of the bit line contacts 240, and thus may be manufactured by a method similar to that of the non-volatile memory device of FIGS. 3A and 3B. However, the position and the size of the preliminary etch stop layer pattern may be different according to the size of the bridge portions B. For example, the preliminary etch stop layer pattern may be formed to have a length in the first direction equal to or longer than about three times a width of each bit line contact 240. Additionally, the bit line contact holes may be formed in a diagonal line in three bridge portions B.

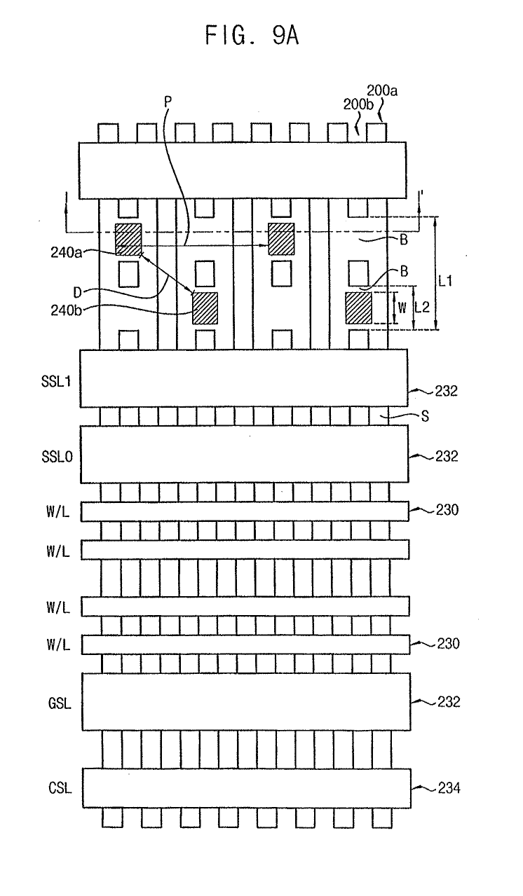

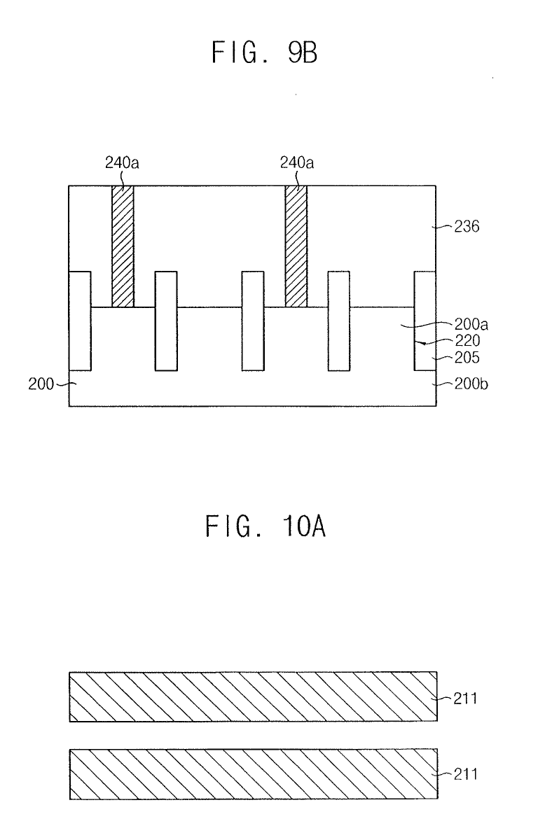

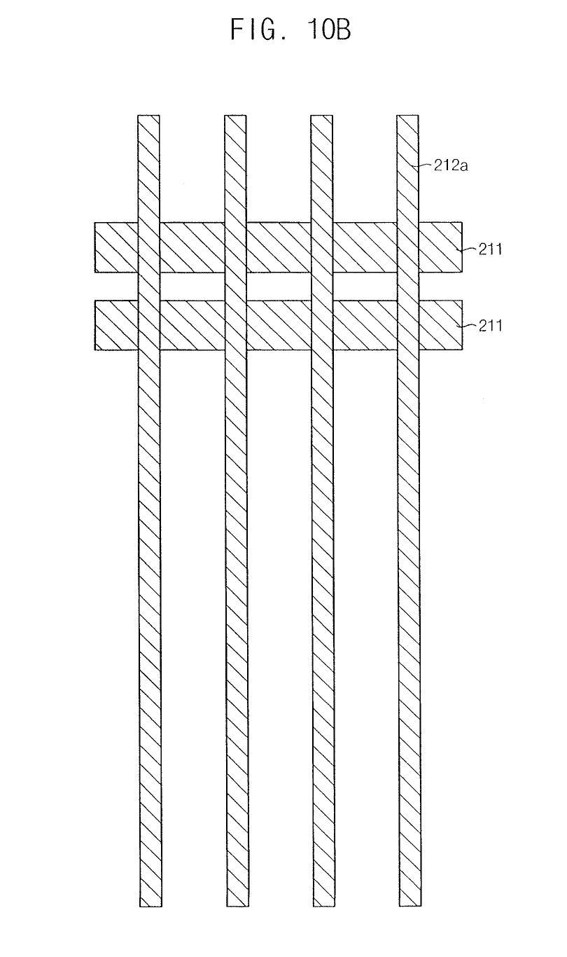

FIG. 9A is a plan view illustrating a memory cell array of a non-volatile memory device in accordance with example embodiments, and FIG. 9B is a cross-sectional view cut along the line I-I′ in FIG. 9A.

The non-volatile memory device of FIGS. 9A and 9B may be substantially the same as that of FIGS. 3A and 3B, except for a length and a size of each bridge portion and a layout of bit line contacts.

Referring to FIGS. 9A and 9B, a substrate 200 may have a plurality of isolation layers 205 thereon. The isolation layers 205 may be formed in a plurality of trenches 220 on the substrate 200. The substrate 200 may be divided into an active region 200a and a field region 200b. The field region 200b may be a region under the isolation layers 205. The active region 200a may be a region defined by sidewalls of the isolation layers 205 and may protrude from bottoms of the isolation trenches 220.

The active region 200a may include a plurality of string portions S extending in a first direction and bridge portions B each of which may connect the string portions S adjacent to each other in a second direction substantially perpendicular to the first direction.

The string portions S may be arranged parallel to each other in the second direction. Cell strings may be formed on the string portions S.

Each bridge portion B may serve as a pad region on which bit line contacts 240a and 240b are formed. Each bridge portion B may connect more than one string portion S having a linear or bar shape. In the present embodiment, each bridge portion B connects two linear string portions S.

Each bridge portion B and string portions S connected by the bridge portion B may form a unit string, and a plurality of unit strings may be arranged in the second direction.

Each bridge portion B may have two rectangular shaped areas arranged in the first direction between two adjacent two string portions S. The rectangular shaped areas may have a length L2 in the first direction longer than the width W of the bit line contacts 240a and 240b in the first direction. Thus, the bit line contacts 240a and 240b may be formed on the rectangular shaped areas.

In the active region 200a, a string selection transistor, cell transistors and a ground selection transistor may be formed on the string portions S. Gates of the transistors may be connected, i.e., the gates may be connected to form gate lines, e.g., string selection line SSL, word lines W/L, and a ground selection line (GSL) extending in the second direction. A common source line CSL electrically connected to a source region of the GSL may be formed. The CSL may be parallel to the GSL.

An insulating interlayer 236 covering the string selection transistor, the cell transistors, the ground selection transistor and a CSL may be formed on the substrate 200. The bit line contacts 240a and 240b may be formed through the insulating interlayer 236 and be electrically connected to a drain region of the SSL. Shared bit lines (not shown) making contact with the bit line contacts 240a and 240b may be formed on the insulating interlayer 236.

The bit line contacts 240a and 240b may be arranged to be in a zigzag form, thereby being spaced apart from each other at a maximum distance.

More particularly, the first bit line contacts 240a that are arranged at odd lines from the left may contact an upper rectangular shaped area of the bridge portion B, and the second bit line contacts 240b that are arranged at even lines from the left may contact a lower rectangular shaped area of the bridge portion B. The first and second bit line contacts 240a and 240b may not overlap in the second direction.

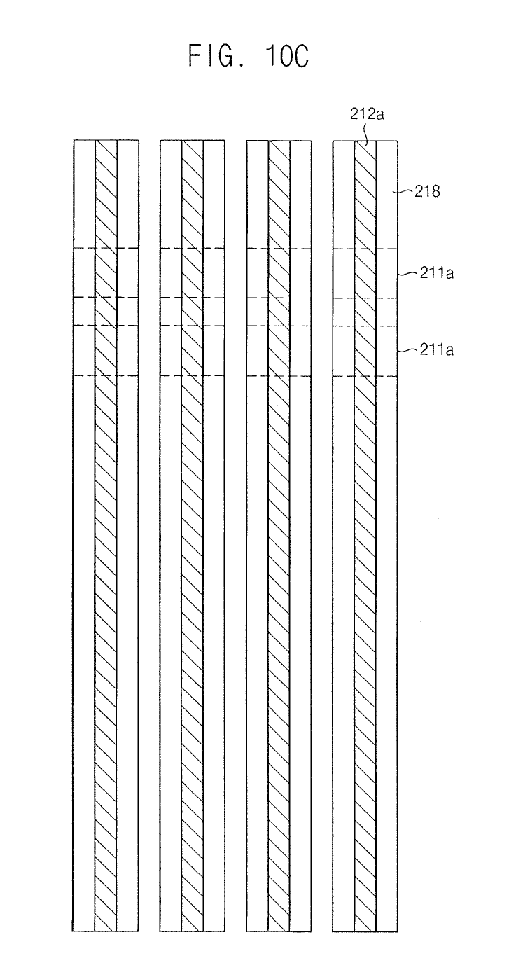

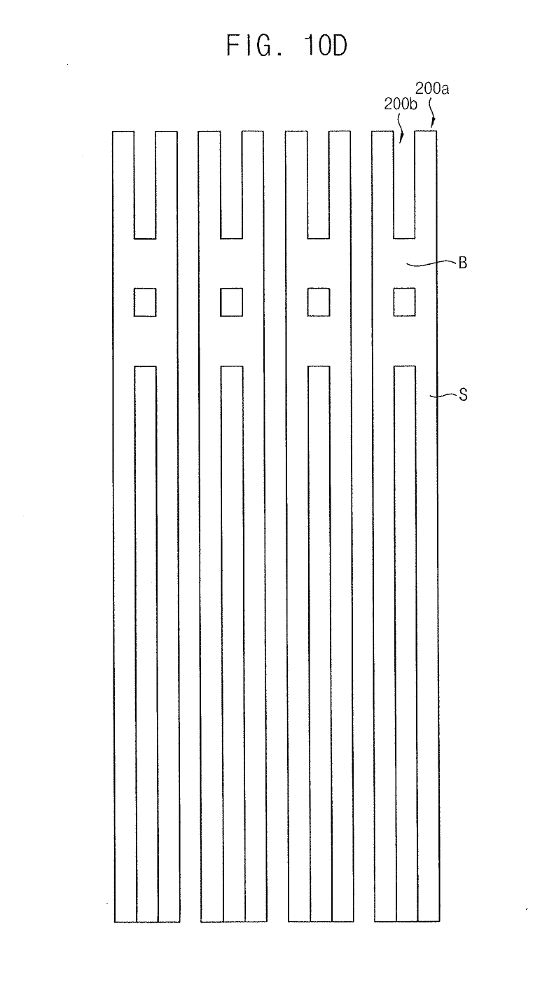

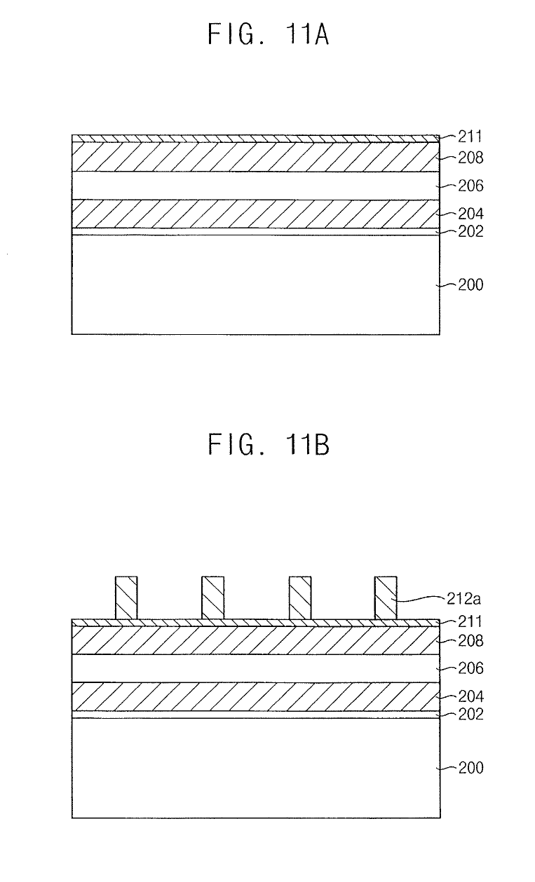

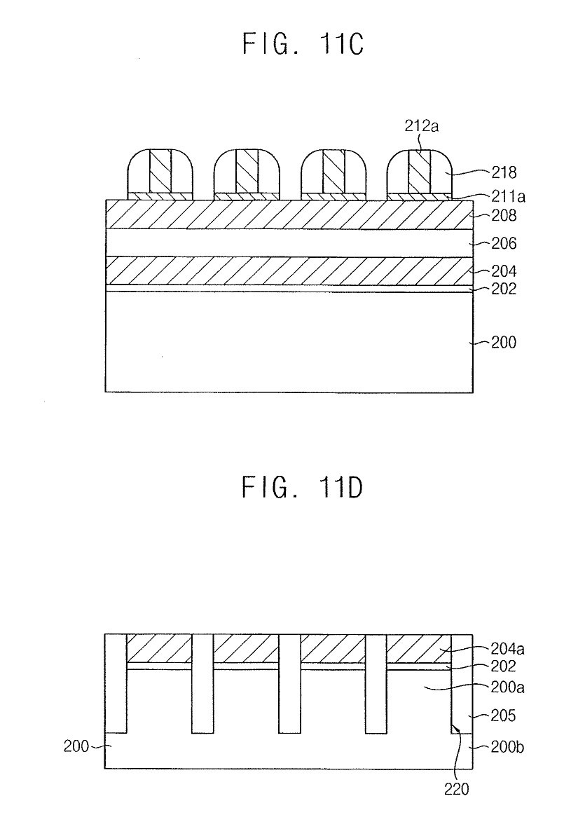

FIGS. 10A to 10D are plan views illustrating stages of a method of manufacturing the non-volatile memory device in FIGS. 9A and 9B. FIGS. 11A to 11D are cross-sectional views illustrating the method, the cross-section views being cut along the line I-I′ of FIG. 9A.

In the present embodiment, an active region may be formed by a quadruple patterning technology (QPT) including one photolithography process and two double patterning processes.

Referring to FIGS. 10A and 11A, a pad layer 202, a first hard mask layer 204, an insulation layer 206, a second hard mask layer 208, and an etch stop layer may be sequentially formed on a substrate 200.

The first and second hard mask layers 204 and 208 may be formed using polysilicon. The insulation layer 206 may be formed using silicon oxide. The insulation layer 206 may be formed by a PECVD process. The etch stop layer may be foamed using a material having an etching selectivity with respect to silicon oxide. For example, the etch stop layer may be formed using silicon nitride.

The etch stop layer may be partially etched to form a preliminary etch stop layer pattern 211 covering bridge portions B (refer to FIG. 9A) of the active region to be subsequently formed and extending in a second direction. In example embodiments, at least two parallel preliminary etch stop layer patterns 211 may be formed in a first direction substantially perpendicular to the second direction.

Each preliminary etch stop layer pattern 211 may be formed to have a length L2 in the first direction, the length L2 being equal to or longer than a width in the first direction of each of bit line contacts 240a and 240b (refer to FIG. 9A) to be subsequently formed.

Referring to FIGS. 10B and 11B, a first temporary mask layer may be formed on the preliminary etch stop layer pattern 211 and the second hard mask layer 208. The first temporary mask layer may be formed to include, e.g., an amorphous carbon layer (ACL). An anti-reflective layer (ARL) (not shown) may be further formed on the first temporary mask layer using silicon oxynitride.

A second preliminary mask layer (not shown) may be formed on the ARL. The second temporary mask layer may be formed using a polymer that is easily removed by an ashing process and/or a stripping process. For example, the second temporary mask layer may be formed using a silicon-based spin-on hardmask (Si-SOH) or a carbon-based spin-on hardmask (C-SOH).

A photoresist pattern (not shown) may be formed from the second temporary mask layer by a photolithography process. The second temporary mask layer may be patterned using the photoresist pattern as an etching mask to form a plurality of second temporary masks.

A first spacer layer may be formed on the second temporary masks and the first temporary mask layer. The first spacer layer may be formed using silicon oxide. The first spacer layer may be formed by, e.g., an atomic layer deposition (ALD) process. The first spacer layer may be formed to have a thickness substantially the same as the width of each string portion S.

The first spacer layer may be anisotropically etched to form a plurality of first spacers. The second temporary masks may be removed so that only the first spacers may remain on the first temporary mask layer. The second temporary masks may be removed by an ashing process and/or a stripping process.

Each first spacer may extend in the first direction and have a width substantially the same as that of each string portion S. Additionally, the first spacers may be spaced apart from each other at a distance about three times the width of each string portion S.

The first temporary mask layer may be etched using the first spacers as an etching mask to form a plurality of first temporary masks 212a on the preliminary etch stop layer pattern 211 and the second hard mask layer 208. The first temporary masks 212a may have a width that is substantially the same as the width of each string portion S. Additionally, the first temporary masks 212a may be spaced apart from each other at a distance of about three times the width of each string portion S.

The first spacers may be removed.

Referring to FIGS. 10C and 11C, a second spacer layer may be formed on the first temporary masks 212a, the preliminary etch stop layer pattern 211 and the second hard mask layer 208. The second spacer layer may be formed using silicon oxide. The second spacer layer may be formed by, e.g., an ALD process. The second spacer layer may be formed to have a thickness that is substantially the same as the width of each string portion S.

The second spacer layer may be anisotropically etched to form a plurality of second spacers 218. The second spacers 218 may be formed on sidewalls of the first temporary masks 212a. Each second spacer 218 may extend in the first direction. The preliminary etch stop layer pattern 211 may be etched using the second spacers 218 as an etching mask to form a plurality of etch stop layer patterns 211a. The etch stop layer patterns 211a may cover the bridge portions B and may have a plurality of (e.g., two) rectangular island shapes in the first direction.

Referring to FIGS. 10D and 11D, the first temporary masks 212a may be removed. Thus, portions of the etch stop layer patterns 211a between the spacers 218 may be exposed.

The second hard mask layer 208 may be etched using the etch stop layer patterns 211a and the second spacers 218 as an etching mask to form a plurality of second hard masks on the first insulation layer 206.

The insulation layer 206 and the first hard mask layer 204 may be etched using the second hard masks as an etching mask to form a first insulation layer pattern (not shown) and a plurality of first hard masks.

The first hard masks may serve as an etching mask for forming isolation trenches 220. The pad layer 202 and the substrate 200 may be etched using the first hard mask 204a as an etching mask to form the isolation trenches 220. The first insulation layer pattern on the first hard masks may be removed during the etching process.

An insulating material, e.g., silicon oxide may be filled into the isolation trenches 220 and planarized to form a plurality of isolation layers 205 in the isolation trenches 220. The substrate 200 may be divided into the active region 200a and a field region 200b by the isolation layers 205. That is, portions of the substrate 200 under the isolation layers 205 may be defined as the field region, and portions of the substrate 200 between sidewalls of the isolation layers 205 may be defined as the active region 200a. The active region 200a may protrude from bottoms of the isolation trenches 220.

As illustrated above, the active region may include string portions S, each of which may extend in the first direction, and bridge portions B, each of which may connect at least adjacent two string portions S. Each bridge portion B may have a plurality of (e.g., two) rectangular shaped areas.

Referring to FIGS. 9A and 9B, cell transistors, string selection transistors and ground selection transistors may be formed. Additionally, a CSL 234 may be formed to be electrically connected to a source region of the ground selection transistor.

An insulating interlayer 236 may be formed to cover the first and second gate structures 230 and 232 and the CSL 234. The insulating interlayer 236 may be partially etched to form bit line contact holes exposing the bridge portions B of the active region. The bit line contact holes may be formed to be arranged in a zigzag form. For example, the bit line contact holes may be formed on an upper rectangular shaped area of the bridge portion B in an odd line from the left and on a lower rectangular shaped area of the bridge portion B in an even line from the left.

A conductive material may be filled into the bit line contact holes to form bit line contacts 240a and 240b.

The bit line contacts 240a and 240b may be arranged in a zigzag form, so that adjacent bit line contacts 240a and 240b may be spaced apart from each other at a long distance. Thus, the bit line contacts 240a and 240b may not be undesirably electrically connected to each other.

Shared bit lines (not shown) may be formed on the insulating interlayer 236 to make contact with the bit line contacts 240a and 240b, respectively. Each shared bit line may be formed to extend in the first direction.

By the above-illustrated processes, the non-volatile memory device may be manufactured.

The non-volatile memory device of FIGS. 9A and 9B may be manufactured by a following method. In the present embodiment, an active region may be formed by one photolithography process and one double patterning process.

Processes substantially the same as those illustrated with reference to FIGS. 10A and 11A may be performed. Particularly, a pad layer 202, a first hard mask layer 204, an insulation layer 206, a second hard mask layer 208 and an etch stop layer may be sequentially formed on a substrate 200. The etch stop layer may be patterned to form a preliminary etch stop layer pattern 211. The preliminary etch stop layer pattern 211 may be formed to extend in a second direction. In example embodiments, at least two parallel preliminary etch stop layer patterns 211 may be formed in a first direction substantially perpendicular to the second direction.

Processes substantially the same as those illustrated with reference to FIGS. 7A and 7B may be performed. That is, a temporary masks and first spacers may be formed on the preliminary etch stop layer patterns 211, and the active region may be formed using the temporary masks and the first spacers. Additionally, transistors and bit line contacts may be formed on the active region to manufacture the non-volatile memory device.

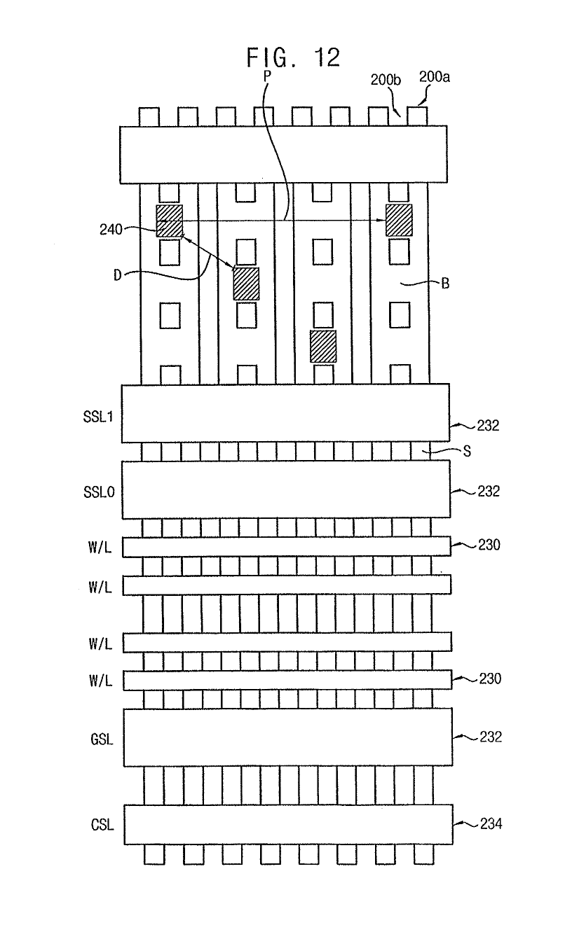

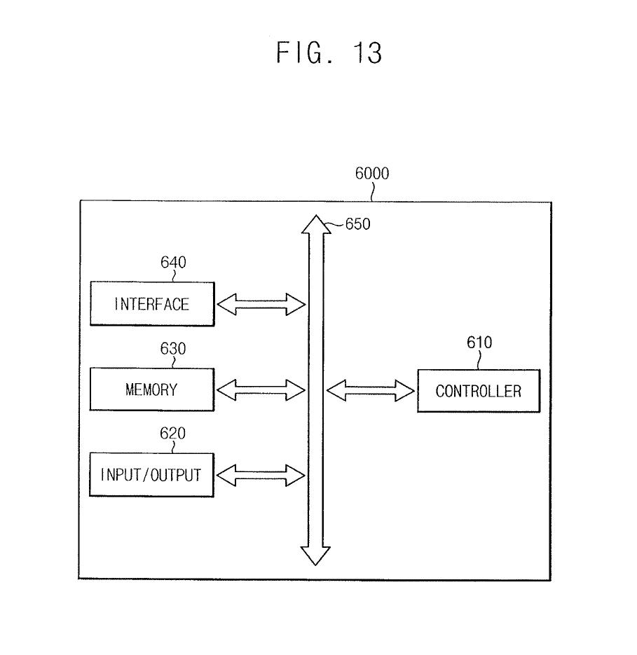

FIG. 12 is a plan view illustrating a memory cell array of a non-volatile memory device in accordance with example embodiments.

The non-volatile memory device of FIG. 12 may be substantially the same as that of FIGS. 9A and 9B, except for the number of rectangular shaped areas included in each bridge portion and a layout of bit line contacts.

Referring to FIG. 12, each bridge portion B may connect more than one string portion S having a linear or bar shape. In the present embodiment, each bridge portion B connects two linear string portions S. Each bridge portion B and string portions S connected by the bridge portion B may form a unit string, and a plurality of unit strings may be arranged in the second direction.

Each bridge portion B may have at least three rectangular shaped areas arranged in the first direction between adjacent two string portions S. When each bridge portion B has three rectangular shaped areas in the first direction, bit line contacts 240 may be arranged in a diagonal line in three bridge portions B. That is, when viewed in the first direction, one bit line contact 240 may be in an upper rectangular shaped area of one bridge portion B, another bit line contact 240 may be in a central rectangular shaped area of another bridge portion B, and the other bit line contact 240 may be in a lower rectangular shaped area of the other bridge portion B. The above layout of the bit line contacts 240 may be repeated in every three bridge portions B. Thus, the bit line contacts 240 may be arranged to be spaced apart from each other at an enlarged distance.

As illustrated above, the non-volatile memory device of FIG. 12 may be substantially the same as that of FIGS. 9A and 9B, and thus may be manufactured by a method substantially the same as that of FIGS. 9A and 9B, i.e., by the method illustrated with reference to FIGS. 10A to 11D.

FIG. 13 is a diagram illustrating an electronic system in accordance with example embodiments.

Referring to FIG. 13, an electronic system 6000 may include a controller 610, an input/output device 620, a memory 630 and an interface 640. The electronic system 6000 may be a mobile system or a system for transferring data. The mobile system may include, e.g., a PDA, a portable computer, a web tablet, a wireless phone, a mobile phone, a digital music player, or a memory card.

The controller 610 may execute a program and control the electronic system 6000. The controller 610 may include, e.g., a microprocessor, a digital signal processor, a micro-controller, and the like. The input/output device 620 may input or output data. The electronic system 6000 may be connected to external devices, e.g., a personal computer or a network and exchange data therewith using the input/output device 620. The input/output device 620 may include, e.g., a keypad, a key board, a display, and the like. The memory 630 may store codes and/or data for operating the controller 610 or codes and/or data processed by the controller 610. The memory 630 may include the non-volatile memory devices in accordance with example embodiments. The interface 640 may serve as a data transfer path between the electronic system 6000 and an external device. The controller 610, the input/output device 620, the memory 630 and the interface 640 may communicate with each other by bus 650. For example, the electronic system 6000 may be applied to a mobile phone, an MP3 player, a navigation system, a portable multimedia player (PMP), a solid state disk (SSD), or household appliances.

As described above, the non-volatile memory device having shared bit lines may be applied to NAND flash memory devices, which may be applied to a mobile phone, an MP3 player, a navigation system, a PMP, a SSD, or household appliances.

By way of summation and review, highly integrated NAND flash memory devices may include shared bit lines. The active region may include string portions for forming cell strings and bridge portions connecting the string portions. The bridge portions may serve as a pad region for bit line contacts.

Because of a high integration degree of memory devices, the width of the bridge portions and the distance therebetween may be very small. Thus, forming bit line contacts at exact positions may not be easy, and sometimes, the bit line contacts may become electrically shorted.

Thus, according to embodiments, each bridge portion may have a length, in a direction perpendicular to an extending direction of word lines, that is equal to or longer than about twice a width of each bit line contact. Additionally, the bit line contacts may be arranged to be spaced apart from each other at a maximum distance, e.g., in a zigzag form or in a diagonal line. By increasing the length of the bridge portions, forming the bridge portions may be easy. Further, misalignment of the bit line contacts may be reduced.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

1.-7. (canceled)

8. A method of manufacturing a non-volatile memory device, the method comprising:
forming an etch stop layer pattern on a substrate;
forming an etching mask on the substrate having the etch stop layer pattern thereon;
etching the substrate using the etching mask and the etch stop layer pattern as an etch mask, the etching mask and the etch stop layer pattern being configured such that the etching of the substrate forms an active region and a field region, the active region including a plurality of string portions and a plurality of bridge portions, the string portions extending in a first direction and being arranged in a second direction substantially perpendicular to the first direction, and the bridge portions connecting at least two adjacent string portions;
forming selection transistors and cell transistors on the active region;
forming bit line contacts on the bridge portions; and
forming shared bit lines electrically connected to the bit line contacts,
wherein each bridge portion is formed to have a length in the first direction equal to or longer than about twice a width of each bit line contact in the first direction.

9. The method as claimed in claim 8, wherein the forming of the etching mask includes:
forming a first temporary mask layer on the substrate;
forming a plurality of first spacers on the first temporary mask layer, the first spacers extending in the first direction;
etching the first temporary mask layer using the first spacers to form a plurality of first temporary masks;
forming a plurality of second spacers on sidewalls of the first temporary masks; and
removing the first temporary masks such that the second spacers remain to constitute the etching mask.

10. The method as claimed in claim 9, wherein the forming of the first spacers includes:
forming a plurality of second temporary masks on the first temporary mask layer;
forming the first spacers on sidewalls of the second temporary masks; and
removing the second temporary masks.

11. The method as claimed in claim 9, wherein the forming of the etch stop layer pattern includes:
forming a preliminary etch stop layer pattern on the substrate, the preliminary etch stop layer pattern extending in the second direction; and
etching the preliminary etch stop layer pattern using the first temporary masks and the second spacers as an etching mask.

12. The method as claimed in claim 11, wherein:
the bridge portions are each formed to have a rectangular island shape, and
the preliminary etch stop layer pattern has a length in the first direction equal to or longer than about twice a width of each bit line contact in the first direction.

13. The method as claimed in claim 11, wherein:
each bridge portion is formed to include at least two rectangular island shaped areas in the first direction, and
the preliminary etch stop layer pattern has a length in the first direction that is equal to or longer than a width of each bit line contact in the first direction.

14. The method as claimed in claim 8, wherein the bit line contacts are arranged in a zigzag form or in one or more diagonal lines, each diagonal line including bit line contacts in three bridge portions.

15. The method as claimed in claim 8, wherein the bit line contacts that are adjacent to each other in the second direction are spaced apart at a maximum distance.

16.-20. (canceled)
